(19) United States
(12) Patent Application Publication
(10) Pub. No.: US 2006/0132252 A1
(43) Pub. Date: Jun. 22, 2006

(54) LOW POWER OSCILLATOR AND METHOD FOR GENERATING AN OSCILLATING SIGNAL

(76) Inventors: Yu-Chin Chu, Hsin-Chu Hsien (TW); Tsung-Wei Shen, Chang-Hua Hsien (TW)

Correspondence Address: NORTH AMERICA INTELLECTUAL PROPERTY CORPORATION, P.O. BOX 506, MERRIFIELD, VA, 22116, US

(21) Appl. No.: 10/906,930

(22) Filed: Mar. 13, 2005

(30) Foreign Application Priority Data
Dec. 17, 2004 (TW) 093139440

(51) Int. Cl. H03B 5/32

(52) U.S. Cl. 331/158

(57) ABSTRACT

A low power oscillator and a method of generating an oscillating signal are disclosed. The low power oscillator includes an oscillating unit for generating a preliminary oscillating signal; an inverter coupled to the oscillating unit in parallel for generating an inverse preliminary oscillating signal fed back to the oscillating unit according to the preliminary oscillating signal, and for generating a first current and a second current according to the preliminary oscillating signal; a first current mirror for generating a first mirror current at an output terminal of the low power oscillator according to the first current; a second current mirror for generating a second mirror current at the output terminal of the low power oscillator according to the second current; and a compensating circuit electrically connected to the inverter for providing a first compensating current and a second compensating current to adjust the first current and the second current, respectively.

### BACKGROUND OF INVENTION

1. Field of the Invention

The present invention relates to an oscillator and a method for generating an oscillating signal, and more specifically, to a low power oscillator and a related method for generating an oscillating signal.

2. Description of the Prior Art

In modern communication technology, a crystal oscillator is a necessary component for providing a clock signal or for generating a carrier signal needed for a modulation. Please refer to FIG. 1. FIG. 1 is a block diagram of a low power oscillator 10 according to a related art. As shown in FIG. 1, the low power oscillator 10 comprises an oscillating unit 12, a plurality of inverters 14 and 16, and a plurality of current mirrors 18 and 22. The oscillating unit 12 comprises a quartz vibrator X₁, a plurality of capacitors C₁ and C₂, and a plurality of resistors R₁ and R₂. The capacitors C₁ and C₂ and the quartz vibrator X₁ are utilized for determining the frequency of an oscillating signal S outputted by the low power oscillator 10. The resistors R₁ and R₂ are utilized for controlling the amplifying ratio of the inverter 14. Therefore, the stability of the low power oscillator 10 can be improved by selecting appropriate resistance values of the resistors R₁ and R₂. The inverter 14 comprises a p-channel metal-oxide semiconductor (PMOS) transistor Q₁ and an n-channel metal-oxide semiconductor (NMOS) transistor Q₂.

When the oscillating unit 12 generates a weak preliminary oscillating signal because of a noise signal, the inverter 14 generates an amplified inverse preliminary oscillating signal according to the preliminary oscillating signal and feeds the amplified inverse preliminary oscillating signal back to the oscillating unit 12. After repeating the steps of feedback and amplifying the inverse preliminary oscillating signal(s), a stable oscillating signal can be generated between the oscillating unit 12 and the inverter 14. When the voltage value of the oscillating signal is greater than a threshold value (i.e. 1.2V), the PMOS transistor Q₁ of the inverter 14 is turned off, and the NMOS transistor Q₂ is turned on to generate a current I₂. Afterwards, the current mirror 22 generates a mirror current I₂′ according to the current I₂. In the same manner, when the oscillating signal is less than a threshold value, the NMOS transistor Q₂ is turned off, and the PMOS transistor Q₁ is turned on. Therefore, the PMOS transistor Q₁ generates a current I₁ and the current mirror 18 generates a mirror current I₁′ according to the current I₁. This is because the directions of the mirror currents I₁′ and I₂′ flowing through the terminal n₀ are opposite. In other words, the mirror current I₁′ flows from the voltage source V_{cc} to the terminal n₀, and the mirror current I₂′ flows from the terminal n₀ to ground. Hence, the voltage level of the terminal n₀ continuously alternates between a high voltage level and a low voltage level. An oscillating signal is therefore generated at the terminal n₀. The inverter 16 according to a related art is a Schmitt Trigger Inverter and is electrically connected to a voltage source V_{cc} and ground (not shown in the FIG. 1). The inverter 16 has a hysteresis phenomenon, therefore a situation in which the output signal outputted by the inverter 16 is oscillated can be avoided, when the inverter 16 is in a changing state. In other words, the inverter 16 can further shape the oscillating signal at the terminal n₀ to generate a better oscillating signal S. In addition, the inverter 16 is electrically connected between the voltage source V_{cc} and ground (the ground terminal), and therefore the amplitude of the oscillating signal S is amplified to a voltage difference between V_{cc} and ground. However, the PMOS transistor Q₃ of the current mirror 18 and the NMOS transistor Q₄ of the current mirror 22 are both diode-connected, so the oscillating rage of the signal at the terminal n₁ will be less than V_{cc}−0 (which means the voltage difference between the voltage level V_{cc} and the ground) due to the voltage differences (i.e. 0.7V) provided by the PMOS transistor Q₃ and the NMOS transistor Q₄. In this way, power consumed by the low power oscillator 10 can be reduced.

Please refer to FIG. 2. FIG. 2 is a diagram describing an I-V curve characteristic of the PMOS transistor Q₃ of the current mirror 18. As shown in FIG. 2, the voltage value of the horizontal axis is the voltage difference between the source and the drain of the PMOS transistors Q₃, and the current value of the vertical axis is the amount of the current following through the source and the drain of the PMOS transistor Q₃. The solid line in FIG. 2 represents the actual I-V characteristic, and the dotted line represents the ideal and linear I-V characteristic. The above-mentioned low power oscillator 10 can efficiently reduce the amount of consumed power. However, the nonlinear I-V characteristic of the transistor indirectly causes the phase stability of the oscillating signal S to get progressively worse.

### SUMMARY OF INVENTION

One of the objectives of the claimed invention is therefore to provide a low power oscillator comprising a compensating circuit, and a related method for generating an oscillating signal to solve the above-mentioned problem.

According to the claimed invention, a low power oscillator is disclosed. The low power oscillator comprises: an oscillating unit having a first terminal and a second terminal for generating a preliminary oscillating signal; an inverter having an input terminal, an output terminal, a first reference terminal and a second terminal, the inverter coupled to the oscillating unit in parallel for generating an inverse preliminary oscillating signal at the output terminal fed back to the second terminal of the oscillating unit according to the preliminary oscillating signal, and for alternately generating a first current at the first reference terminal and a second current at the second reference terminal according to the preliminary oscillating signal, wherein the input terminal is electrically connected to the first terminal of the oscillating unit, and the output terminal is electrically connected to the second terminal of the oscillating unit; a first current mirror having an input terminal, a first output terminal and a second output terminal, the first current mirror utilized for generating a first mirror current at an output terminal of the low power oscillator according to the first current, wherein the input terminal of the first current mirror is electrically connected to the first reference terminal of the inverter, the first output terminal of the first current mirror is electrically connected to a first voltage level, and the second output terminal of the first current mirror is electrically connected to the output terminal of the low power oscillator; a second current mirror having an input terminal, a first output terminal and a second output terminal, the second current mirror utilized for generating a second mirror current at the output terminal of the low power oscillator according to the second current, wherein the input terminal of the second current mirror is electrically connected to the second reference terminal of the inverter, the first output terminal of the second current mirror is electrically connected to the output terminal of the low power oscillator, and the second output terminal of the second current mirror is electrically connected to a second voltage level that is lower than the first voltage level; and a compensating circuit electrically connected to both the first and the second reference terminals of the inverter for respectively providing a first compensating current and a second compensating current for respectively adjusting the first current and the second current.

In addition, the claimed invention provides a method for generating an oscillating signal. The method comprises: generating a preliminary oscillating signal; inverting the preliminary oscillating signal to generate an inverse preliminary oscillating signal, and feeding the inverse preliminary oscillating signal back to be the preliminary oscillating signal; alternately generating a first current and a second current according to the preliminary oscillating signal; generating a first mirror current at an output terminal according to the first current by utilizing a current mirror; generating a second mirror current at the output terminal according to the second current by utilizing a current mirror; and providing a first compensating current and a second compensating current to respectively adjust the first current and the second current; wherein the directions of the first mirror current and the second mirror current flowing out of the output terminal are opposite in order to generate the oscillating signal.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a block diagram of a low power oscillator according to a related art.

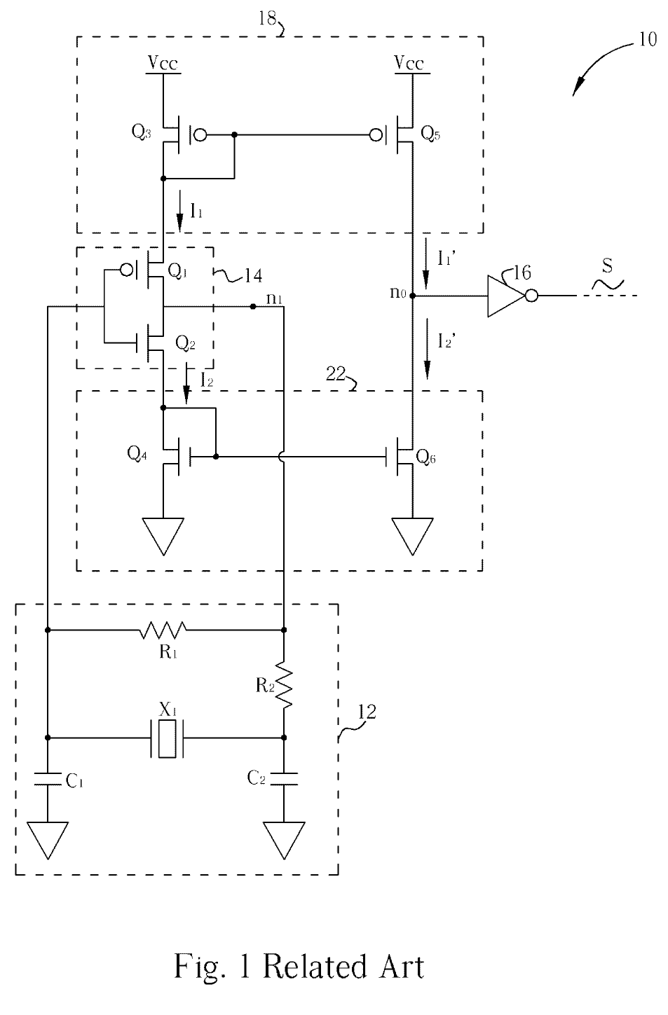

FIG. 2 is a diagram describing an I-V curve characteristic of a PMOS transistor shown in FIG. 1.

FIG. 3 is a block diagram of a low power oscillator according to a preferred embodiment of the present invention.

FIG. 4 is a diagram describing I-V curve characteristics of two PMOS transistors coupled in parallel shown in FIG. 3.

### DETAILED DESCRIPTION

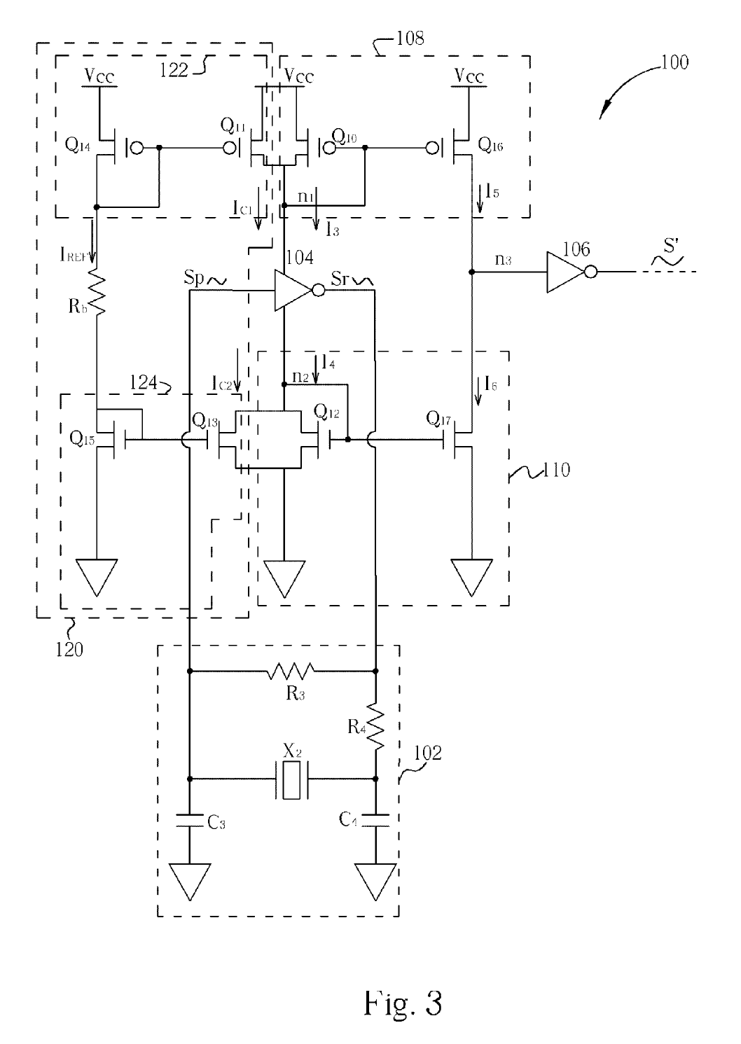

Please refer to FIG. 3. FIG. 3 is a block diagram of a low power oscillator 100 according to a preferred embodiment of the present invention. As shown in FIG. 3, the low power oscillator 100 comprises an oscillating unit 102, a plurality of inverters 104 and 106, a plurality of current mirrors 108 and 110, and a compensating circuit 120. The oscillating unit 102 comprises a quartz vibrator X₂, a plurality of capacitors C₃ and C₄ and a plurality of resistors R₃ and R₄. The quartz vibrator X₂, the capacitors C₃ and C₄ are utilized for determining a frequency of an oscillating signal S′ outputted by the low power oscillator 100. The resistors R₃ and R₄ are utilized for controlling an amplifying ratio of the inverter 104 and improving the stability of the low power oscillator 100 by choosing appropriate resistance values of the resistors R₃ and R₄. Therefore, a circuit formed by the oscillating unit 102 and the inverter 104 generates a preliminary oscillating signal Sₚ at an input terminal of the inverter 104, and generates an inverse preliminary oscillating signal Sᵣ at an output terminal of the inverter 104. When the voltage level of the preliminary oscillating signal Sₚ is higher than a threshold value, the current mirror 108 is disenabled and does not generate any mirror current. However, at the same time the current mirror 110 is enabled, and it generates a corresponding mirror current I₆ according to a current I₄. On the other hand, when the voltage level of the preliminary oscillating signal Sₚ is lower than a threshold value, the current mirror 108 is enabled and generates a corresponding mirror current I₅ according to a current I₃. Meanwhile, the current mirror 110 is disenabled and does not generate any current.

In the present embodiment, the compensating circuit 120 comprises a resistor R_{b} and a plurality of current mirrors 122 and 124. The resistor R_{b} is utilized for providing a resistance. Hence, the PMOS transistor Q₁₄, the NMOS transistor Q₁₅ and the resistor R_{b} can generate a reference current I_{REF} between V_{cc} and ground (the ground terminal). The current mirrors 122 and 124 then generate compensating currents I_{C1} and I_{C2} according to the reference current I_{REF} to respectively compensate currents flowing through the terminal n₁ and the terminal n₂. Therefore, when the current mirror 108 is enabled, the current flowing through the terminal n₁ becomes I₃+I_{C1}. When the current mirror 110 is enabled, the current flowing through the terminal n₂ becomes I₄+I_{C2}. For the low power oscillator 100 of the preferred embodiment of the present invention, the mirror ratios of the current mirrors 122 and 124 are equal. However, it should be noted that the mirror ratio can be adjusted by adjusting the ratios of width to length (W/L) of the PMOS transistors Q₁₁ and Q₁₄, in order to control the amount of the compensating current I_{C1} according to design requirements. Similarly, the mirror ratio can be adjusted by adjusting the ratios of width to length (W/L) of the NMOS transistors Q₁₃ and Q₁₅, in order to control the amount of the compensating current I_{C2} according to design requirements. The above-mentioned variations are all covered by the present invention.

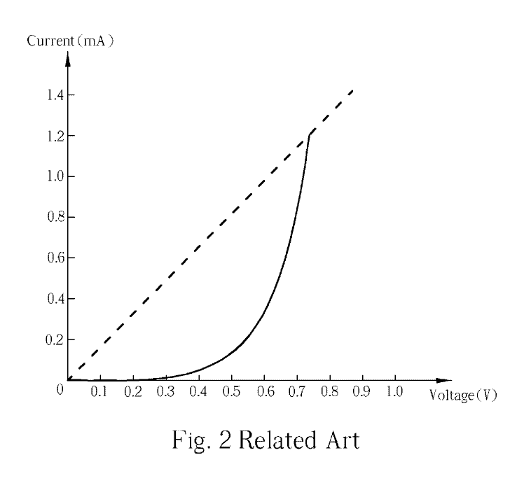

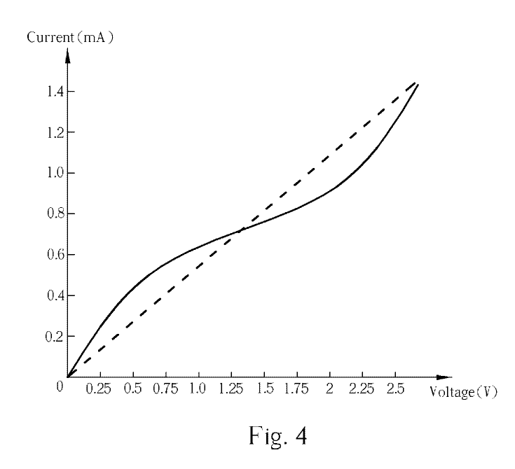

Please refer to FIG. 4. FIG. 4 is a diagram describing I-V curve characteristics of the two PMOS transistors Q₁₀ and Q₁₁ shown in FIG. 3. The solid line in FIG. 4 represents the actual I-V characteristic, and the dotted line represents the ideal and linear I-V characteristic. The voltage value of the horizontal axis is the respective voltage differences between the sources and the drains of the PMOS transistors Q₁₀ and Q₁₁, and the current value of the vertical axis is the total amount of the current following through the terminal n₁. When the voltage value of the terminal n₁ is less than a threshold value, the PMOS transistors Q₁₀ and Q₁₁ are turned on, and the current I₃ and the compensating current I_{C1} are generated at the same time. Meanwhile, a current flowing through the terminal n₁ is I₃+I_{C1}. Hence, compared to FIG. 2, the I-V characteristic is more linear in the present embodiment. In addition, in a process of designing a circuit, the amounts of the current I₃ and the compensating current I_{C1} can be adjusted by adjusting the ratios of width to length (W/L) of the NMOS transistors Q₁₀ and Q₁₁, in order to adjust the required I-V characteristic curve. In the same manner, when the voltage value of the terminal n₂ is greater than a threshold value, the NMOS transistors Q₁₂ and Q₁₃ are both turned on, so the current I₄ and the compensating current I_{C2} are generated at the same time. Meanwhile, a current flowing through the terminal n₂ is I₄+I_{C2}. Hence, the current mirror 110 also can change the I-V characteristic curve by the compensating current I_{C2} generated by the current mirror 124 in the compensating circuit, in order to make the I-V characteristic curve of the NMOS transistor Q₁₂ more linear through the loads provided by the NMOS transistors Q₁₂ and Q₁₃. Additionally, as mentioned above, the amounts of the current I₄ and the compensating current I_{C2} can be adjusted by adjusting the ratios of width to length (W/L) of the NMOS transistors Q₁₂ and Q₁₃, in order to adjust the required I-V curve characteristics.

Finally, the current mirrors 108 and 110 generate a mirror current I₅ according to the current I₃ and the compensating current I_{C1} and generate a mirror current I₆ according to the current I₄ and the compensating current I_{C2}, and then an oscillating signal on a specific frequency can be generated at the terminal n₃. Additionally, the inverter 106 (a Schmitt Trigger Inverter) shapes the wave shape of the outputted oscillating signal S′. For the low power oscillator 100 of the preferred embodiment of the present invention, the mirror ratios of the current mirrors 108 and 110 are equal. However, it should be noted that the mirror ratio can be adjusted by adjusting the ratios of width to length of the PMOS transistors Q₁₀ and Q₁₆, so the amount of the mirror current I₅ can be adjusted according to design requirements. In the same manner, according to the present invention, the mirror ratio can be adjusted by adjusting the ratios of width to length of the NMOS transistors Q₁₂ and Q₁₇, so the amount of the mirror current I₆ can be adjusted according to design requirements.

In contrast to the related art, the low power oscillator according to the present invention utilizes the compensating circuit 120 to generate the compensating currents I_{C1} and I_{C2} to respectively compensate currents flowing through the terminal n₁ and the terminal n₂, and a single transistor is further compensated for its nonlinear I-V characteristic when the single transistor provides a load. In addition, the value of the reference current I_{REF} can be adjusted according to the resistance value of the resistor R_{b}, and the compensating currents I_{C1} and I_{C2} can be further adjusted. The low power oscillator according to the present invention can lower the degree of non-linearity of the I-V characteristics by using compensating currents I_{C1}, I_{C2}. In this way, the low power oscillator according to the present invention not only keeps the characteristic of low power consumption, but can also efficiently improve the phase stability of the outputted oscillating signal.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A low power oscillator, comprising:
an oscillating unit having a first terminal and a second terminal for generating a preliminary oscillating signal;
an inverter having an input terminal, an output terminal, a first reference terminal and a second terminal, the inverter coupled to the oscillating unit in parallel for generating an inverse preliminary oscillating signal at the output terminal fed back to the second terminal of the oscillating unit according to the preliminary oscillating signal, and for alternately generating a first current at the first reference terminal and a second current at the second reference terminal according to the preliminary oscillating signal, wherein the input terminal is electrically connected to the first terminal of the oscillating unit, and the output terminal is electrically connected to the second terminal of the oscillating unit;
a first current mirror having an input terminal, a first output terminal and a second output terminal, the first current mirror utilized for generating a first mirror current at an output terminal of the low power oscillator according to the first current, wherein the input terminal of the first current mirror is electrically connected to the first reference terminal of the inverter, the first output terminal of the first current mirror is electrically connected to a first voltage level, and the second output terminal of the first current mirror is electrically connected to the output terminal of the low power oscillator;
a second current mirror having an input terminal, a first output terminal and a second output terminal, the second current mirror utilized for generating a second mirror current at the output terminal of the low power oscillator according to the second current, wherein the input terminal of the second current mirror is electrically connected to the second reference terminal of the inverter, the first output terminal of the second current mirror is electrically connected to the output terminal of the low power oscillator, and the second output terminal of the second current mirror is electrically connected to a second voltage level that is lower than the first voltage level; and
a compensating circuit electrically connected to both the first and the second reference terminals of the inverter for respectively providing a first compensating current and a second compensating current for respectively adjusting the first current and the second current.

2. The low power oscillator of claim 1, wherein the compensating circuit comprises:
a resistor unit for providing a predetermined resistance value to control an amount of a reference current flowing through the resistor unit;
a third current mirror having a first input terminal, a second input terminal and an output terminal, and the third current mirror utilized for generating a third mirror current to be the first compensating current according to the reference current, wherein the output terminal of the third current mirror is electrically connected to the first reference terminal of the inverter, the first input terminal of the third current mirror is electrically connected to a third voltage level, and the second input terminal of the third current mirror is electrically connected to a terminal of the resistor unit; and
a fourth current mirror having a first input terminal, a second input terminal and an output terminal, and the fourth current mirror utilized for generating a fourth mirror current to be the second compensating current according to the reference current, wherein the output terminal of the fourth current mirror is electrically connected to the second reference terminal of the inverter, the first input terminal of the fourth current mirror is electrically connected to another terminal of the resistor unit, and the second input terminal of the fourth current mirror is electrically connected to a fourth voltage level, and the fourth voltage level is lower than the third voltage level.

3. The low power oscillator of claim 2, wherein the first voltage level is equal to the third voltage level, and the second voltage level is equal to the fourth voltage level.

4. The low power oscillator of claim 3, wherein the second voltage level and the fourth voltage level are ground voltages.

5. The low power oscillator of claim 2, wherein the mirror ratio of the first current mirror is equal to the mirror ratio of the second current mirror, and the mirror ratio of the third current mirror is equal to the mirror ratio of the fourth current mirror.

6. The low power oscillator of claim 2, wherein the first current mirror comprises:
a first p-channel metal-oxide semiconductor (PMOS) transistor, wherein a drain of the first PMOS transistor is the input terminal of the first current mirror and is electrically connected to a gate of the first PMOS transistor, and a source of the first PMOS transistor is electrically connected to the first voltage level; and
a second PMOS transistor, wherein a source of the second PMOS transistor is the first output terminal of the first current mirror, a drain of the second PMOS transistor is the second output terminal of the first current mirror and a gate of the second PMOS transistor is electrically connected to the gate of the first PMOS transistor; and
the third current mirror, comprising:
a first PMOS transistor, wherein a source of the first PMOS transistor is the first input terminal of the third current mirror, a drain of the first PMOS transistor is the second input terminal of the third current mirror and is electrically connected to a gate of the first PMOS transistor; and
a second PMOS transistor, wherein a drain of the second PMOS transistor is the output terminal of the third current mirror, a gate of the second PMOS transistor is electrically connected to the gate of the first PMOS transistor, and a source of the second PMOS transistor is electrically connected to the third voltage level.

7. The low power oscillator of claim 2, wherein the second current mirror comprises:
a first n-channel metal-oxide semiconductor (NMOS) transistor, wherein a drain of the first NMOS transistor is the input terminal of the second current mirror and is electrically connected to a gate of the first NMOS transistor, and a source of the first NMOS transistor is electrically connected to a second voltage level; and
a second NMOS transistor, wherein a drain of the second NMOS transistor is the first output terminal of the third current mirror, a gate of the second NMOS transistor is electrically connected to the gate of the first NMOS transistor, and a source of the second NMOS transistor is a second output terminal of the third current mirror; and
the fourth current mirror, comprising:
a first NMOS transistor, wherein a drain of the first NMOS transistor is the first input terminal of the fourth current mirror and is electrically connected to a gate of the first NMOS transistor, and a source of the first NMOS transistor is the second input terminal of the fourth current mirror; and
a second NMOS transistor, wherein a drain of the second NMOS transistor is the output terminal of the fourth current mirror, a gate of the second NMOS transistor is electrically connected to the gate of the first NMOS transistor, and a source of the second NMOS transistor is electrically connected to the fourth voltage level.

8. The low power oscillator of claim 1, wherein the oscillating unit comprises:
a quartz vibrator having a first terminal and a second terminal;
a first capacitor electrically connected between the first terminal of the quartz vibrator and a ground terminal;
a second capacitor electrically connected between the second terminal of the quartz vibrator and the ground terminal;
a first resistor electrically connected between the output terminal of the inverter and the second terminal of the quartz vibrator; and
a second resistor coupled to the quartz vibrator in parallel.

9. A method for generating an oscillating signal, comprising:
generating a preliminary oscillating signal;
inverting the preliminary oscillating signal to generate an inverse preliminary oscillating signal, and feeding the inverse preliminary oscillating signal back to be the preliminary oscillating signal;
alternately generating a first current and a second current according to the preliminary oscillating signal;
generating a first mirror current at an output terminal according to the first current by utilizing a current mirror;
generating a second mirror current at the output terminal according to the second current by utilizing a current mirror; and
providing a first compensating current and a second compensating current to respectively adjust the first current and the second current;
wherein the directions of the first mirror current and the second mirror current flowing out of the output terminal are opposite in order to generate the oscillating signal.

10. The method of claim 9, wherein the step of providing the first and the second compensating currents comprises:
providing a reference current;
generating a third mirror current to be the first compensating current according the reference current by utilizing a current mirror; and
generating a fourth mirror current to be the second compensating current according the reference current by utilizing a current mirror.

11. The method of claim 10, wherein a mirror ratio utilized for generating the first current mirror is equal to a mirror ratio utilized for generating the second current mirror, and a mirror ratio utilized for generating the third current mirror is equal to a mirror ratio utilized for generating the fourth current mirror.
